(19) United States
(12) Patent Application Publication
(10) Pub. No.: US 2025/0079772 A1
(43) Pub. Date: Mar. 6, 2025

(54) RADIATION SHIELDING CONFORMAL COAT FOR PRINTED BOARD ASSEMBLY

(71) Applicant: Honeywell International Inc., Charlotte, NC (US)

(72) Inventors: Pedro Luis Lebron, San Antonio, PR (US); Jonathan E. Shick, Tampa, FL (US); Robert Alan Martinson, Ramsey, MN (US)

(73) Assignee: Honeywell International Inc., Charlotte, NC (US)

(21) Appl. No.: 18/458,774

(22) Filed: Aug. 30, 2023

(51) Int. Cl. H01R 13/6599; H05K 1/02; H05K 3/28

(52) U.S. Cl. CPC H01R 13/6599; H05K 1/0218; H05K 3/284; H05K 2201/0715

(57) ABSTRACT

A method and device for providing radiation shielding is disclosed. The method comprises fabricating a circuit card assembly that includes a grounding region configured to prevent a floating metal, wherein the grounding region is connected to a chassis ground. The method further comprises forming a polymeric composition metallized with a high-Z material, wherein the high-Z material is effective to provide radiation shielding for the circuit card assembly. The method also comprises applying a conformal coat of the polymeric composition metallized with the high-Z material over the circuit card assembly including the grounding region. The conformal coat is effective to provide radiation protection for the circuit card assembly when exposed to an ionizing radiation environment.

### BACKGROUND

Electronics systems often require a variety of ionizing radiation shielding schemes dependent upon the specific environments of the target application. As such, a common approach to radiation shielding of sensitive electronics is to form sheet metal shields around the exterior, or throughout the interior, of the electronics enclosure. This approach poses a variety of challenges, including, but not limited to: manufacturability and assembly due to geometric dimensioning and tolerancing, cost, weight, assembly complexity, build time, special handling requirements, and the like. Often, all-encompassing enclosure shielding is not feasible for these reasons, which may drive the need for component-level shielding, or “spot” shielding, which includes the bonding (or other form of attachment) of a small sheet metal shield under and/or around a component. This in turn impacts available circuit board real estate.

Size and mass are especially critical metrics for aerospace and satellite applications, and applying radiation shielding globally by building the shielding into the electronics enclosure can pay a major penalty. Resulting mass-reduction activities may drive significant non-recurring engineering costs into developments, and often these efforts focus on strategically placing the shielding more locally and closer to the components to be protected.

### SUMMARY

A method and device for providing radiation shielding is disclosed herein. The method comprises fabricating a circuit card assembly that includes a grounding region configured to prevent a floating metal, wherein the grounding region is connected to a chassis ground. The method further comprises forming a polymeric composition metallized with a high-Z material, wherein the high-Z material is effective to provide radiation shielding for the circuit card assembly. The method also comprises applying a conformal coat of the polymeric composition metallized with the high-Z material over the circuit card assembly including the grounding region. The conformal coat is effective to provide radiation protection for the circuit card assembly when exposed to an ionizing radiation environment.

### BRIEF DESCRIPTION OF THE DRAWINGS

Features of the present invention will become apparent to those skilled in the art from the following description with reference to the drawings. Understanding that the drawings depict only typical embodiments and are not therefore to be considered limiting in scope, the invention will be described with additional specificity and detail using the accompanying drawings, in which:

FIG. 1 is a flow diagram of a method of forming a radiation shielding conformal coat over a circuit card assembly, according to an exemplary implementation;

FIG. 2 is a schematic cross-sectional side view of a device including a circuit card assembly with a radiation shielding conformal coat, according to one embodiment; and

FIG. 3 is a schematic cross-sectional side view of a device including a circuit card assembly with a radiation shielding conformal coat, according to another embodiment.

### DETAILED DESCRIPTION

In the following detailed description, embodiments are described in sufficient detail to enable those skilled in the art to practice the invention. It is to be understood that other embodiments may be utilized without departing from the scope of the invention. The following detailed description is, therefore, not to be taken in a limiting sense.

Various embodiments and methods of forming a radiation shielding conformal coat, for a printed board assembly (PBA) and similar devices, are described herein.

Conventional radiation shielding approaches are typically used for shielding against electromagnetic interference (EMI), such as radio frequency interference (RFI). It should be noted that shielding against ionizing radiation is a distinct discipline from shielding against EMI and RFI due to the differences in the fundamental physics of the types of radiation and their mechanisms of interaction with electronic systems.

In one approach, a circuit card assembly is provided that includes a grounding region for a conformal coat metallized with a high-Z material. A conformal coat metallized with the high-Z material is applied over the circuit card assembly. The conformal coat metallized with the high-Z material provides radiation shielding to the circuit card assembly. This radiation shielding is effective to provide radiation protection against an ionizing radiation environment for the circuit card assembly. In another approach, a high-Z material layer is deposited on top of the applied conformal coat over the circuit card assembly, to provide board-level radiation protection against an ionizing radiation environment.

The term “high-Z” material used herein refers to high atomic number (high-Z) chemical elements, such as tungsten, tantalum, or the like.

An example design method using the present techniques follows. Initially, radiation environments are identified to establish an overall shielding approach, to determine the level of conformal coat metallization needed per device. A circuit card is designed to include a high-Z conformal coat grounding region to prevent floating metal. This grounding region will be free of a standard conformal coat, and will be tied to a chassis ground. A conformal coat is then applied to the assembled circuit card (minus the grounding region). Particles composed of a high-Z material are embedded within the conformal coat by mixing the high-Z material within the conformal coat prior to application on the circuit card assembly. These particles provide radiation shielding at board level. The density of the particles and the specific material (e.g., tungsten, tantalum) are design parameters that may be adjusted depending on the design requirements. Alternatively, an additional high-Z coating layer can be applied over the conformal coat using various deposition techniques, such as physical vapor deposition, electrostatic spray-assisted vapor deposition, chemical vapor deposition, or the like, after application of the conformal coat.

The present methods provides a circuit board designer with the ability to design a shielding scheme that places the shielding directly to the specific regions requiring the shielding, while avoiding such shielding where it does not provide significant benefit relative to its mass penalty. The present approach, when combined with additional radiation shielding strategies, allows for a comprehensive radiation shielding scheme while reducing assembly part count and complexity.

The present approaches offer an additional capability to the shielding designer to consider in the design process, potentially reducing development effort and costs. Further, some programs require that the geometric properties of the shield be verified (especially its thickness) during the production phase of the project. A traditional formed or machined metal shield would have to be scrapped if this verification failed. However, the present methods allow for additional layers of the coating material to be applied to increase thickness without scrapping the assembly.

Further details regarding the present approach are described as follows and with reference to the drawings.

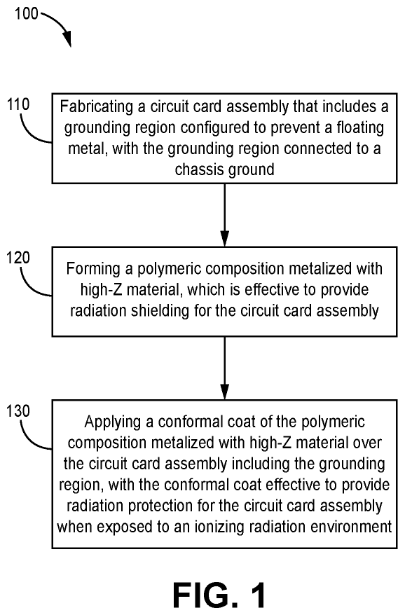

FIG. 1 is a flow diagram of an example method 100 for implementing the present approach. The method 100 comprises fabricating a circuit card assembly that includes a grounding region configured to prevent a floating metal, with the grounding region connected to a chassis ground (block 110). The method 100 further includes forming a polymeric composition metallized with high-Z material, which is effective to provide radiation shielding for the circuit card assembly (block 120). The method 100 then comprises applying a conformal coat of the polymeric composition metallized with high-Z material over the circuit card assembly including the grounding region, with the conformal coat effective to provide radiation protection for the circuit card assembly when exposed to an ionizing radiation environment (block 130).

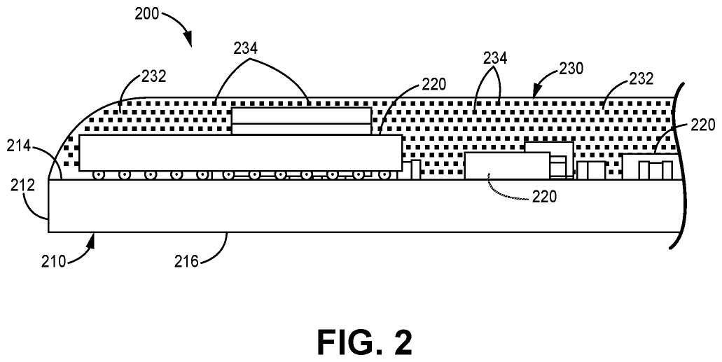

FIG. 2 is a schematic side view of a device 200, with a radiation shielding conformal coat, according to one embodiment. The device 200 includes a circuit card assembly 210 that includes a printed circuit board 212 having an upper surface 214 and an opposing lower surface 216. A set of electronic components 220, such as one or more inertial sensors, processor chips, memory chips, or the like, are mounted on upper surface 214 according to standard connection techniques. A grounding region is located on circuit card assembly 210 and is configured to prevent a floating metal. The grounding region is connected to a chassis ground (not shown).

A conformal coat 230 is formed over electronic components 220 on upper surface 214 of printed circuit board 212 including the grounding region. The conformal coat 230 comprises a polymeric material 232 that is metallized with particles of a high-Z material 234 embedded in polymeric material 232. The conformal coat 230 can be formed over circuit card assembly 210 using various deposition techniques. The conformal coat 230 is formed to provide radiation shielding to circuit card assembly 210, with the radiation shielding effective to provide radiation protection against an ionizing radiation environment.

Non-limiting examples of polymeric material 232 include acrylic materials, polyurethane materials, parylene, combinations thereof, or the like. Non-limiting examples of high-Z material 234 include tungsten, tantalum, combinations thereof, or the like.

The density and size of the particles of high-Z material, as well as the type of high-Z material, can be selected as needed depending on the design requirements of circuit card assembly 210. For example, the density of the particles of high-Z material 234, embedded in polymeric material 232, can range from about 10% to about 90%; and the size of the particles of high-Z material 234 can range from about 1 micron to about 100 microns. In addition, polymeric material 232 can have a thickness range from about 0.001 inch to about 0.003 inch.

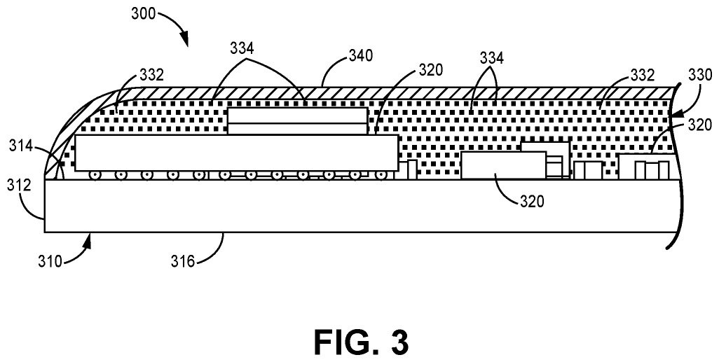

FIG. 3 is a schematic side view of a device 300 with radiation shielding, according to another embodiment. The device 300 includes a circuit card assembly 310 that includes a printed circuit board 312 having an upper surface 314 and an opposing lower surface 316. A set of electronic components 320, such as one or more inertial sensors, processor chips, memory chips, or the like, are mounted on upper surface 314 according to standard connection techniques. A grounding region is located on circuit card assembly 310 and is configured to prevent a floating metal. The grounding region is connected to a chassis ground (not shown).

A conformal coat 330 is formed over electronic components 320 on upper surface 314 of printed circuit board 312 including the grounding region. The conformal coat 330 comprises a polymeric material 332, and metallic particles 334 composed of a high-Z material, which are embedded in polymeric material 332. In addition, a coating layer 340 is formed over conformal coat 330, with coating layer 340 comprising a high-Z material.

The conformal coat 330 and coating layer 340 can be formed over circuit card assembly 310 using various deposition techniques such as physical vapor deposition, electrostatic spray-assisted vapor deposition, or the like. The conformal coat 330 and coating layer 340 provide radiation shielding to circuit card assembly 310, with the radiation shielding effective to provide radiation protection against an ionizing radiation environment.

In one embodiment, the high-Z material of coating layer 340 can be the same as the high-Z material of conformal coat 330. In another embodiment, the high-Z material of the coating layer is different than the high-Z material of the conformal coat.

Non-limiting examples of polymeric material 332 include acrylic materials, polyurethane materials, parylene, combinations thereof, or the like. Non-limiting examples of the high-Z material used in conformal coat 330 and coating layer 340 include tungsten, tantalum, combinations thereof, or the like.

The density and size of the particles of high-Z material used in conformal coat 330, as well as the type of high-Z material, can be selected as needed depending on the design requirements of circuit card assembly 310. For example, the density of the particles of the high-Z material can range from about 10% to about 90%; and the size of the particles of the high-Z material can range from about 1 micron to about 100 microns. In addition, conformal coat 330 can have a thickness in a range from about 0.001 inch to about 0.003 inch, and coating layer 340 can have a thickness in a range from about 0.001 inch to about 0.003 inch.

In other embodiments, a conformal coat without a high-Z material is formed over a the circuit card assembly, and a coating layer of a high-Z material is deposited over the top of the conformal coat to provide radiation protection against an ionizing radiation environment.

### Example Embodiments

Example 1 includes a method comprising: fabricating a circuit card assembly that includes a grounding region configured to prevent a floating metal, wherein the grounding region is connected to a chassis ground; forming a polymeric composition metallized with a high-Z material, wherein the high-Z material is effective to provide radiation shielding for the circuit card assembly; and applying a conformal coat of the polymeric composition metallized with the high-Z material over the circuit card assembly including the grounding region, wherein the conformal coat is effective to provide radiation protection for the circuit card assembly when exposed to an ionizing radiation environment.

Example 2 includes the method of Example 1, wherein the circuit card assembly includes a set of electronic components mounted on a printed circuit board, the electronic components comprising one or more inertial sensors, one or more processor chips, or one or more memory chips.

Example 3 includes the method of any of Examples 1-2, wherein the polymeric composition includes a polymeric material comprising an acrylic material, a polyurethane material, parylene, or combinations thereof.

Example 4 includes the method of any of Examples 1-3, wherein the high-Z material comprises tungsten, tantalum, or combinations thereof.

Example 5 includes the method of any of Examples 1-4, wherein the conformal coat of the polymeric composition is embedded with particles of the high-Z material.

Example 6 includes the method of any of Examples 1-5, further comprising: forming a coating layer over the conformal coat of the polymeric composition metallized with the high-Z material, the coating layer including the high-Z material; wherein the conformal coat and the coating layer provide the radiation shielding to the circuit card assembly.

Example 7 includes the method of Example 6, wherein the high-Z material of the coating layer is the same as the high-Z material of the conformal coat.

Example 8 includes the method of Example 6, wherein the high-Z material of the coating layer is different than the high-Z material of the conformal coat.

Example 9 includes the method of any of Examples 6-8, wherein the high-Z material of the coating layer comprises tungsten, tantalum, or combinations thereof.

Example 10 includes a device comprising: a circuit card assembly that includes a grounding region, wherein the grounding region is configured to prevent a floating metal and is connected to a chassis ground; and a conformal coat including a polymeric composition metallized with a high-Z material, the conformal coat over the circuit card assembly including the grounding region; wherein the conformal coat is configured to provide radiation shielding to the circuit card assembly, the radiation shielding effective to provide radiation protection against an ionizing radiation environment.

Example 11 includes the device of Example 10, wherein the circuit card assembly includes a set of electronic components mounted on a printed circuit board, the electronic components comprising one or more inertial sensors, one or more processor chips, or one or more memory chips.

Example 12 includes the device of any of Examples 10-11, wherein the polymeric composition includes a polymeric material comprising an acrylic material, a polyurethane material, parylene, or combinations thereof.

Example 13 includes the device of any of Examples 10-12, wherein the high-Z material comprises tungsten, tantalum, or combinations thereof.

Example 14 includes the device of any of Examples 10-13, wherein the conformal coat of the polymeric composition is embedded with particles of the high-Z material.

Example 15 includes the device of Example 14, wherein: a density of the particles of the high-Z material, embedded in the polymeric composition, ranges from about 10% to about 90%; and a size of the particles of the high-Z material ranges from about 1 micron to about 100 microns.

Example 16 includes the device of any of Examples 10-15, further comprising: a coating layer over the conformal coat, the coating layer including a high-Z material; wherein the conformal coat and the coating layer provide the radiation shielding to the circuit card assembly.

Example 17 includes the device of Example 16, wherein the high-Z material of the coating layer is the same as the high-Z material of the conformal coat.

Example 18 includes the device of Example 16, wherein the high-Z material of the coating layer is different than the high-Z material of the conformal coat.

Example 19 includes the device of any of Examples 16-18, wherein the high-Z material of the coating layer comprises tungsten, tantalum, or combinations thereof.

Example 20 includes a method comprising: providing a circuit card assembly that includes a grounding region for a conformal coat metallized with a high-Z material, wherein the grounding region is configured to prevent a floating metal and is connected to a chassis ground; applying the conformal coat metallized with the high-Z material over the circuit card assembly; and forming a coating layer over the conformal coat metallized with the high-Z material, the coating layer composed of a high-Z material; wherein the conformal coat and the coating layer provide radiation shielding to the circuit card assembly, the radiation shielding effective to provide radiation protection against an ionizing radiation environment.

From the foregoing, it will be appreciated that, although specific embodiments have been described herein for purposes of illustration, various modifications may be made without deviating from the scope of the disclosure. Thus, the described embodiments are to be considered in all respects only as illustrative and not restrictive. In addition, all changes that come within the meaning and range of equivalency of the claims are to be embraced within their scope.

What is claimed is:

1. A method comprising:
fabricating a circuit card assembly that includes a grounding region configured to prevent a floating metal, wherein the grounding region is connected to a chassis ground;
forming a polymeric composition metallized with a high-Z material, wherein the high-Z material is effective to provide radiation shielding for the circuit card assembly; and
applying a conformal coat of the polymeric composition metallized with the high-Z material over the circuit card assembly including the grounding region, wherein the conformal coat is effective to provide radiation protection for the circuit card assembly when exposed to an ionizing radiation environment.

2. The method of claim 1, wherein the circuit card assembly includes a set of electronic components mounted on a printed circuit board, the electronic components comprising one or more inertial sensors, one or more processor chips, or one or more memory chips.

3. The method of claim 1, wherein the polymeric composition includes a polymeric material comprising an acrylic material, a polyurethane material, parylene, or combinations thereof.

4. The method of claim 1, wherein the high-Z material comprises tungsten, tantalum, or combinations thereof.

5. The method of claim 1, wherein the conformal coat of the polymeric composition is embedded with particles of the high-Z material.

6. The method of claim 1, further comprising:
forming a coating layer over the conformal coat of the polymeric composition metallized with the high-Z material, the coating layer including the high-Z material;
wherein the conformal coat and the coating layer provide the radiation shielding to the circuit card assembly.

7. The method of claim 6, wherein the high-Z material of the coating layer is the same as the high-Z material of the conformal coat.

8. The method of claim 6, wherein the high-Z material of the coating layer is different than the high-Z material of the conformal coat.

9. The method of claim 6, wherein the high-Z material of the coating layer comprises tungsten, tantalum, or combinations thereof.

10. A device comprising:
a circuit card assembly that includes a grounding region, wherein the grounding region is configured to prevent a floating metal and is connected to a chassis ground; and
a conformal coat including a polymeric composition metallized with a high-Z material, the conformal coat over the circuit card assembly including the grounding region;
wherein the conformal coat is configured to provide radiation shielding to the circuit card assembly, the radiation shielding effective to provide radiation protection against an ionizing radiation environment.

11. The device of claim 10, wherein the circuit card assembly includes a set of electronic components mounted on a printed circuit board, the electronic components comprising one or more inertial sensors, one or more processor chips, or one or more memory chips.

12. The device of claim 10, wherein the polymeric composition includes a polymeric material comprising an acrylic material, a polyurethane material, parylene, or combinations thereof.

13. The device of claim 10, wherein the high-Z material comprises tungsten, tantalum, or combinations thereof.

14. The device of claim 10, wherein the conformal coat of the polymeric composition is embedded with particles of the high-Z material.

15. The device of claim 14, wherein:
a density of the particles of the high-Z material, embedded in the polymeric composition, ranges from about 10% to about 90%; and
a size of the particles of the high-Z material ranges from about 1 micron to about 100 microns.

16. The device of claim 10, further comprising:
a coating layer over the conformal coat, the coating layer including a high-Z material;
wherein the conformal coat and the coating layer provide the radiation shielding to the circuit card assembly.

17. The device of claim 16, wherein the high-Z material of the coating layer is the same as the high-Z material of the conformal coat.

18. The device of claim 16, wherein the high-Z material of the coating layer is different than the high-Z material of the conformal coat.

19. The device of claim 16, wherein the high-Z material of the coating layer comprises tungsten, tantalum, or combinations thereof.

20. A method comprising:
providing a circuit card assembly that includes a grounding region for a conformal coat metallized with a high-Z material, wherein the grounding region is configured to prevent a floating metal and is connected to a chassis ground;
applying the conformal coat metallized with the high-Z material over the circuit card assembly; and
forming a coating layer over the conformal coat metallized with the high-Z material, the coating layer composed of a high-Z material;
wherein the conformal coat and the coating layer provide radiation shielding to the circuit card assembly, the radiation shielding effective to provide radiation protection against an ionizing radiation environment.
